(19) United States
(12) Patent Application Publication
(10) Pub. No.: US 2008/0242551 A1
(43) Pub. Date: Oct. 2, 2008

(54) Wire-in-conduit magnetic conductor technology

(76) Inventor: Thomas A. Painter, Tallahassee, FL (US)

Correspondence Address: J. WILEY HORTON, ESQUIRE;Pennington, Moore, Wilkinson, Bell & Dunbar, P.A., 215 S. Monore Street, 2nd Floor, Post Office Box 10095, Tallahassee, FL, 32302-2095, US

(21) Appl. No.: 12/079,198

(22) Filed: Mar. 25, 2008

Related U.S. Application Data
(60) Provisional application No. 60/920,062, filed on Mar. 26, 2007.

(51) Int. Cl. H01L 39/24; H01L 39/04

(52) U.S. Cl. 505/431; 505/150; 505/500

(57) ABSTRACT

A new type of conductor well-suited for use in a superconducting electromagnet. The conductor comprises a single electrically conductive member at its core. The conductor may include concentric layers of dissimilar materials. This conductor is surrounded by a channel through which coolant—typically liquid helium—can flow. The channel is bounded by a metal conduit of sufficient strength to withstand the Lorentz forces. The metal conduit is covered by an insulator which forces the current into the desired helical path.

### CROSS-REFERENCES TO RELATED APPLICATIONS

This is a non-provisional patent application claiming the benefit—pursuant to 37 C.F.R. section 1.53(c) of an earlier filed provisional application. The earlier application was filed Mar. 26, 2007 and was assigned Ser. No. 60/920,062. It listed the same inventor.

### STATEMENT REGARDING FEDERALLY SPONSORED RESEARCH OR DEVELOPMENT

This invention was developed at the National High Magnetic Field Laboratory in Tallahassee, Fla. The research and development has been federally sponsored.

### MICROFICHE APPENDIX

Not Applicable

### BACKGROUND OF THE INVENTION

1. Field of the Invention

This invention relates to the field of electromagnets. More specifically, the invention comprises a new type of conductor construction which is well suited to high field strength electromagnets.

2. Description of the Related Art

Conductors for use in electromagnets are well known in the art. In this context, a “conductor” is defined as an assembly of a current carrying element, a structural element, an insulating element, and a heat transfer enabling element. A single element may assume more than one role. As a very simple example, low strength electromagnets are made by wrapping plastic-coated copper wire around a ferromagnetic core. The copper wire is both the current carrying element and the structural element. The plastic coating is the insulating element (which forces the electrical current to pass only in the helical direction). The heat transfer enabling element is comprised of conduction through the plastic coating followed by transfer to the surrounding air.

High field strength electromagnets are obviously more complex. Recent advances in low temperature superconductors have made many new materials available. The conductivity of such materials is but one consideration among many. High field strength magnets create substantial Lorentz forces, which generally tend to separate the conductor coils (Lorentz forces represent a complex phenomenon which may act in many directions. However, for this disclosure, it suffices to say that if they are not counteracted, they tend to blow the magnet apart).

Key issues for selecting a conductor typically include the following:

1. Current density;

2. Stability (discussed in more detail subsequently);

3. Mechanical strength;

4. Insulation;

5. Manufacturability;

6. Persistence;

7. Susceptibility to coupling currents;

8. Strain sensitivity and irreversibility (i.e., plastic deformation); and

9. Susceptibility to inductive losses.

Recent advances in material science have made many new high temperature superconducting (“HTS”) materials available, including Bi2212. Such materials may be used in magnets having very high field strengths, such as 20T or more. Low temperature superconducting (“LTS”) materials may also be used. Examples include NbTi and Nb₃Sn. The terms “high temperature” and “low temperature” may be misleading to those outside the field, since the difference between the two would not ordinarily be deemed significant. LTS material is typically operated around 4.2 K to maintain superconductivity, while HTS material can be operated as high as 77 K.

Magnets have been constructed using HTS materials, LTS materials, and combinations of the two. However, stability problems can exist in such magnets when conventional conductor technology is used. Those skilled in the art will know that superconducting materials must generally be cooled to very low temperatures before exhibiting superconductivity. Liquid helium is often used as a coolant (sometimes forcibly circulated through the magnet). The term “stability” refers primarily to the stability of the superconducting state of the wire against energy deposition, which can raise the temperature of the wire above its critical superconducting temperature. When the superconducting materials are cooled to below their critical temperatures (often near absolute zero), a sudden and precipitous drop in resistance occurs. So long as the conductor is maintained in this desired temperature range, the resistance will be very low, current flow can be very high, and a high strength field can be produced.

The high current flow in and of itself does not produce significant heat. However, a changing current, as is required when the magnet is ramped up to its operational field, produces heat in the superconducting wire. This heat must be carried away by the cooling system. If the cooling system is deficient at some point, the local temperature may rise out of the superconducting band. When this occurs, resistance in that region will rise dramatically and much more heat will be produced. This phenomenon becomes self-accelerating, resulting in the loss of superconductivity.

Thus, most such magnets must be thoroughly cooled, after which the current must be slowly “ramped up.” The heat capacity of the materials approaches zero when in the superconducting temperature band. Any slight energy addition can push local temperature out of the superconducting band. Such energy deposition can be caused by small events such as epoxy cracking or wire motion. Thus, all these factors effect stability and limit the rate at which the current can be “ramped up.” Current must therefore be increased very slowly.

Prior art cable-in-conduit conductors (“CIC” conductors) largely overcome this stability problem by allowing liquid helium to circulate in close proximity to the superconductor cable (separated only by a conduit, insulating material, or in some instances both). Thus, any localized temperature “spikes” are quickly cooled and the unstable ramp up phenomenon is largely avoided. Unfortunately, CIC conductors have other problems.

Because they employ multiple superconducting wires along a single electrical path, they are prone to boundary induced coupling currents. These currents are generated between wires within a cable due to non-uniform cable transpositions and non-uniform magnetic flux over the length of the CIC conductor. These coupling currents reduce the available ramp rate. They also erode field homogeneity, which is crucial in some applications. Creating persistent junctions between multi-conductor cables is also known to be difficult. A conductor assembly having a single conductor in a conduit could potentially solve many of these problems.

### BRIEF SUMMARY OF THE INVENTION

The present invention comprises a new type of conductor well-suited for use in a superconducting electromagnet. The conductor comprises a single electrically conductive member at its core. The conductor may include concentric layers of dissimilar materials. This conductor is surrounded by a channel through which coolant—typically liquid helium—can flow. The channel is bounded by a metal conduit of sufficient strength to withstand the Lorentz forces. The metal conduit is covered by an insulator which forces the current into the desired helical path.

### BRIEF DESCRIPTION OF THE SEVERAL VIEWS OF THE DRAWINGS

FIG. 1 is a perspective view, showing the present invention.

FIG. 2 is a section view, showing the present invention.

FIG. 3 is a perspective view, showing a helical winding made using the present invention.

FIG. 4 is a perspective view with a cutaway, showing a winding pack made with the present invention.

FIG. 5 is a perspective view, showing additional structural details of the present invention.

### REFERENCE NUMERALS IN THE DRAWINGS

| | | | |
|---|---|---|---|
| 10 | WIC Conductor | 12 | wire |
| 14 | coolant channel | 16 | conduit |
| 18 | insulator | 20 | helix |
| 22 | winding pack | 24 | superconducting material |
| 26 | wire matrix material | 28 | coolant flow |

### DETAILED DESCRIPTION OF THE INVENTION

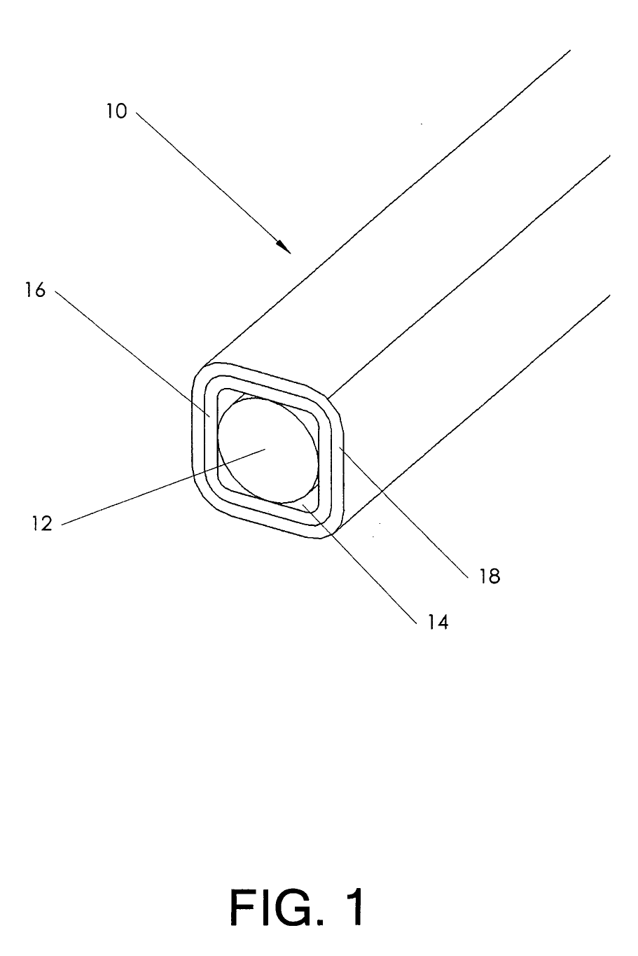

FIG. 1 shows a conductor constructed according to the present invention, denoted as wire-in-conduit conductor 10 (“WIC” Conductor). Wire 12 is at the center (a single conductive element). This is preferably made of a superconducting material capable of carrying high current densities when suitably cooled. Conduit 16 surrounds wire 12. The reader will observe that conduit 16 has a square cross section with a fillet at each corner. It touches wire 12 (or comes very close to touching) near the middle of each side of the square. Gaps are formed near the corners of the square. These gaps form coolant channel 14 (which may be continuous if the conduit does not quite touch the wire, or may be four separate channels if it does). Conduit 16 is surrounded by insulator 18.

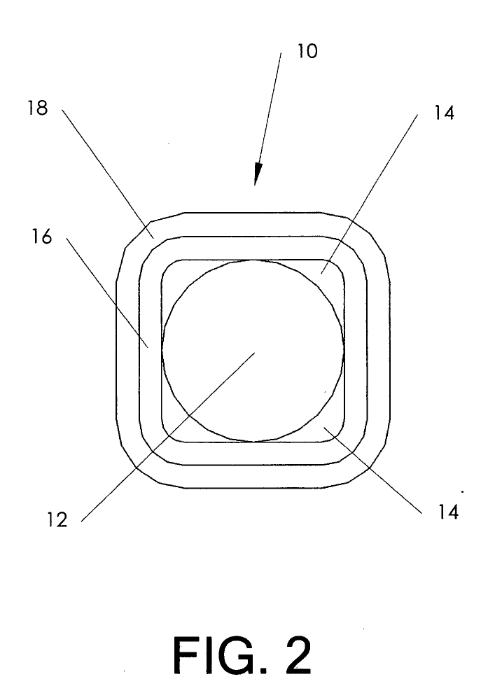

FIG. 2 shows WIC conductor 10 in a sectional elevation view. The components shown collectively carry out the functions needed for the conductor. Wire 12 is made of a superconducting material, such as Nb₃Sn or Bi2212. Such a material, when suitably cooled, can withstand current densities in the range of 300 A/mm². However, it is not strong enough to withstand the Lorentz forces created by such a current density. Conduit 16 is preferably a strong metal which can withstand the Lorentz forces. It may by conductive, and it may be in contact with the wire along the WIC Conductor. However, because its resistance is so much higher than the wire, it will not carry substantial current. Suitable materials for the conduit include stainless steel or other high strength alloys.

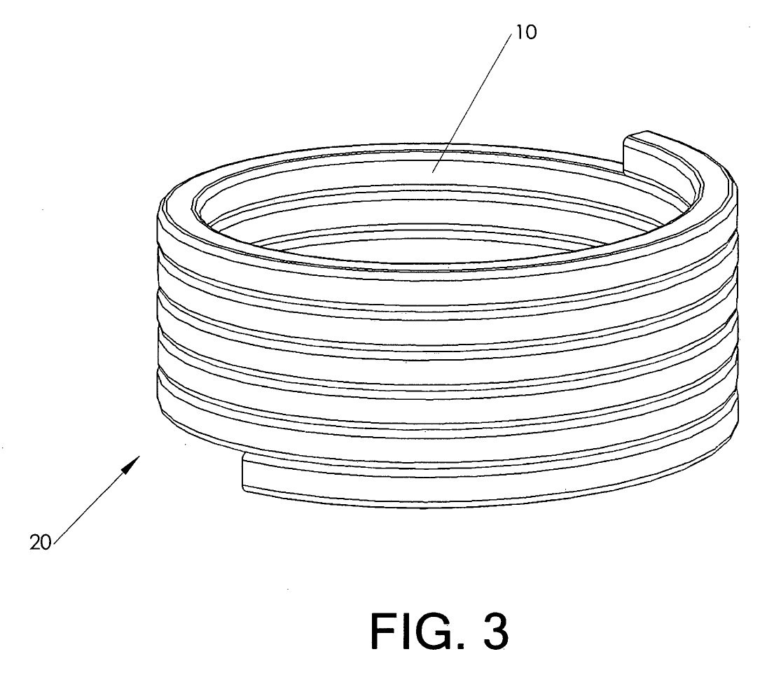

The WIC conductor can be used to carry current in many types of electromagnets, as well as other applications. FIG. 3 shows a very simple electromagnet created by wrapping a WIC conductor into a helix 20. Returning to FIG. 2, the reader will observe that conduit 16 is covered by insulator 18. The insulator is necessary in order to force the current path along the helix.

Insulator 18 is made of a material having a very low electrical conductivity. It must also be fairly tough, since it must not crack or break under the stress and strain conditions created by the Lorentz forces and cooling.

The material selected for insulator 18 will generally have a very low thermal conductivity as well. Thus, cooling the WIC conductor by passing a coolant over the outside of the insulation will not be very effective. For this reason, coolant is preferably forced through coolant channel 14 directly around wire 12. This choice requires the use of inlet and outlet manifolds, pumps, valves, and similar hardware. Such hardware is known in the art and has not been illustrated for this reason.

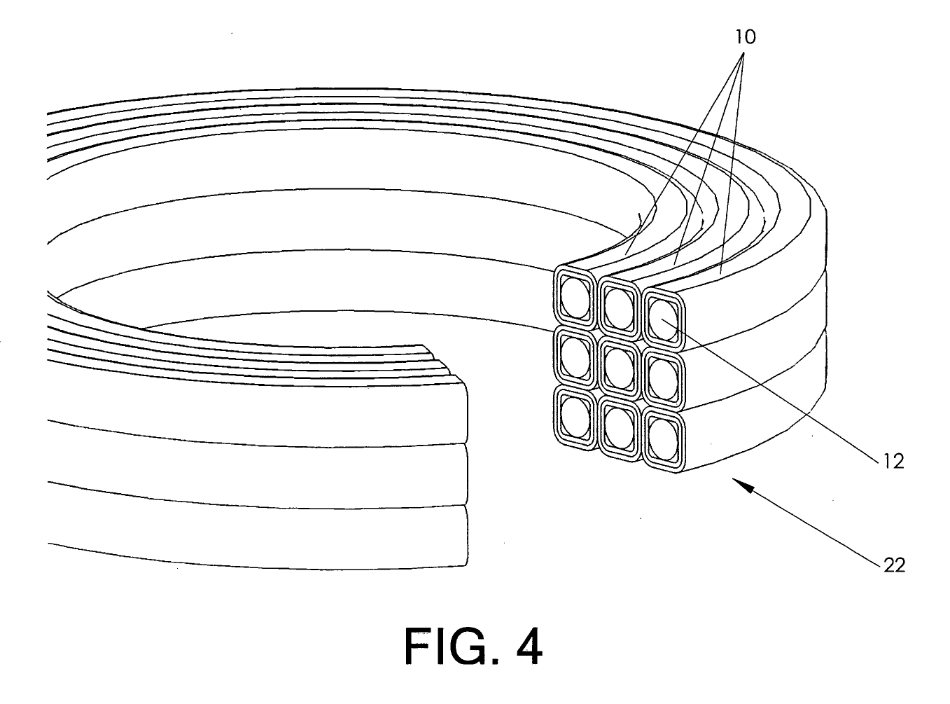

Of course, a powerful magnet generally must include a nested stack of many coils. FIG. 4 shows one such magnet made using WIC conductors (three helices nested together). A cutaway has been made to reveal the uniform internal features of the WIC conductors. Such a magnet is not restricted to WIC conductors of uniform size. A variety of sizes can be used to create desired field characteristics.

An example of an effective WIC conductor is useful to the reader's understanding. Using Bi2212 superconducting material, a wire of 0.8 mm diameter can be used. This wire can be placed within a square conduit having a wall thickness of 0.076 mm (including suitable corner fillets). The conduit's internal passage is preferably sized to just allow clearance for the wire (It is preferable for the wire to be bound securely by the conduit so that it does not move within the conduit under Lorentz loading). Insulation is of course added. An electromagnet can then be constructed using this WIC conductor in a suitable arrangement. For a 30 T field (corresponding to 1.28 GHz), the computed winding pack current densities range between 60 A/mm² and 130 A mm².

The stability of a magnet made with this technology is greatly increased by the fact that the coolant circulates around and in direct contact with the superconducting wire. In addition, the choice of material for the wire can be made without consideration of its mechanical strength, since that function is met primarily by the conduit.

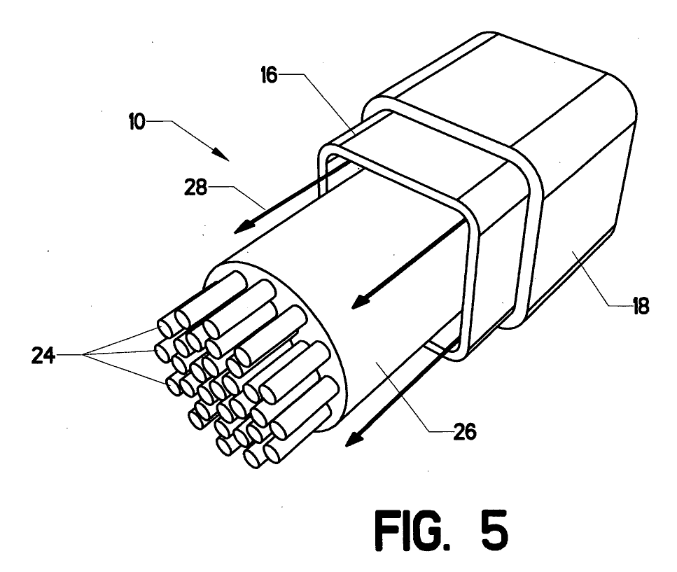

FIG. 5 is a perspective view of the wire in conduit conductor showing some additional details. Superconducting materials are generally embedded in a conventional carrier material so that they may be formed into a long conductor. A brief description of the manufacturing process may be helpful: Copper can be used as a “carrier” material. The process begins with an elongated copper cylinder. A gun drill is used to drill a series of parallel holes through the cylinder. These holes are parallel to the cylinder's central axis. The superconducting material is then placed in the parallel holes.

The assembly then goes through a series of drawing processes to increase its length and reduce its diameter. Heat treating processes are also used to prevent the mechanical deformation of the drawing processes from producing unwanted properties. The result is a cluster of superconducting wires embedded in a matrix material. In FIG. 5, these are denoted as superconducting material 24 and surrounding wire matrix material 26.

Conduit 16 is a relatively strong material. It is formed as a long and hollow section. Matrix material 26, along with the embedded superconducting material, is then slipped inside the conduit along its entire length. Once the conductor is in place, the conduit is reduced in size until it closely encompasses the conductor and assumes the shape shown in the illustrations. This can be done by a variety of known techniques, such as by passing the assembly through a linear forming die. Insulator 18 is then added over the top using any one of a variety of known techniques—such as coating, spraying, dipping, and the like. The completed assembly will typically be quite long. It is therefore advantageous to wind it onto a spool for storage until it is needed.

FIG. 5 shows only a very small portion of the length of a typical wire in conduit assembly. The reader will observe how the round conductor within the square conduit creates coolant flow passages near each corner. Coolant flow 28 can be forced through these passages as shown by the arrows.

The interface between the conduit and the conductor can take various forms. The conduit can be necked down until it barely touches the conductor at four points along the circumference of the circle. It can be further compressed so that it actually creates four compressed flats on the conductor's circumference. On the other hand, some embodiments may actually leave a small gap between the conductor and the conduit. Such an embodiment will still function, since the Lorentz forces will force the conductor against the conduit once a significant electrical current is applied.

Now that the basic structure of the wire in conduit design has been disclosed, some additional details can be understood in the proper context. Those skilled in the art will know that most high-field magnets are constructed of several subassemblies having differing characteristics. As an example, a 30 Tesla magnet can be constructed using several different combinations of conductor and conduit materials. The following examples are representative of the many variations possible:

### Material Selection Example

A magnet having HTS and LTS portions will likely require different materials for these two portions. The HTS sections can use Haynes 25 Alloy conduit and Bi-2212 conductors. The critical current densities for these materials are reported in H Miao, K. R. Marken et. al, “Development of Bi-2212 conductors for magnet applications,” Transactions on the International Cryogenic Materials Conference, vol. 50(B), Anchorage, Ak., pp. 603-611; and J. Schwartz et. al., “Transport critical current measurements to 45 T and upper critical fields of YBa2Cu3O7-delta and Bi2Sr2CaCu2O2+delta,” submitted Phys Rev Lett, 2004.

The LTS portions can use Haynes 242 Alloy conduit and Nb₃Sn conductor. Another portion can use 316LN stainless steel conduit and NbTi conductor. Of course, all the conduit materials must be able to provide suitable mechanical properties at very low temperatures. Recent testing indicates that the Haynes 25 Alloy will provide the highest strength in the annealed condition. Both haynes 25 and 242 are nickel alloys that should prevent cation migration and poisoning of the Bi-2212. Stainless steel 316LN was chosen as well characterized high strength steel compatible for processing with NbTi conductor.

### 30 T Magnet Design Example

A 30 T all superconducting magnet design is presented using materials capable of satisfying acceptable design margins for superconducting magnets used in a wire-in-conduit (“WIC”) conductor configuration. The allowable stress in the conduit—which is primarily responsible for resisting the Lorentz forces—is set at ⅔ of the yield stress or ½ of the ultimate stress. The acceptable current density is set at 60% of the critical current for the HTS conductor and 90% of the critical current for the LTS conductor.

The strain limit in the Bi-2212 is set at 0.25%. However, this strain limit is inconsequential as the limit of conduit stress is reached long before the Bi-2212 strain limit is reached. As a starting point, the normal state current density across only the conventional materials in the conducting matrix (excluding the superconducting portions) is kept below 400 A/mm². Finite element analysis can be used to optimize the conduit wall thickness in order to provide the needed strength.

As mentioned previously, the wire in conduit conductor must operate in a cryogenic environment when included in a high-field magnet. The preferred embodiment operates at 1.8 K, though this is not essential. Operation at 1.8 K minimizes the amount of expensive HTS conductor that must be used by allowing the operation of LTS conductors at higher fields.

The preferred coolant is a bath of sub-cooled, superfluid helium. This will allow the immediate removal of local hot spots without generating relatively unstable helium vapor. However, the present design could be modified to allow operation in a 4.2 K saturated liquid helium environment or a 4.5 K or higher supercritical liquid helium environment.

The preferred embodiment for the 30 T coil structure uses a twelve coil set. The six inner coils use Bi-2212 conductor and Haynes 25 conduit. The next three coils use Nb₃ Sn conductor and Haynes 242 conduit. The outer three coils use NbTi conductor and 316LN conduit.

The radial thickness of the Bi-2212 coils were kept to less than 25 mm based on the expectation that thin coils will be required to maintain the temperature tolerance requirement for the Bi-2212 heat treatments. The radial thickness of the LTS coils was maintained at about 55 mm. The radial separation between coils was set at about 5 mm to allow for coil formers and manufacturing tolerances. The insulation thickness around the conduit was maintained at about 0.125 mm.

The ratio of half height to inner radius for the innermost coil was set at 3, corresponding to 95% of the maximum central field achievable from the innermost layer. The remaining coil heights, except for the two outermost coils, were set such that their uppermost turns contribute equally to the central field as the uppermost turns of the innermost coil. The heights of the two outermost coils were set equal to the third outermost coil to reduce the axial Lorentz loading from the radial fringe fields for those coils. The resultant operating current is 370 A, and the inductance os 805H, or a total stored energy of 55 MJ. The mechanical stress within all coils is maintained within acceptable limits.

The WIC conductor configuration is capable of satisfying the electrical current and structural design constraints for a superconducting magnet. Specific design issues must still be resolved, such as selection of a suitable helium environment, superconducting quench protection, conductor fabrication, heat treatment processing and the like. There are also other design details common to all HTS magnets.

Although the preceding description contains significant detail, it should not be viewed as limiting the scope of the invention but rather as providing illustrations of the preferred embodiments of the invention.

1. A method of making a wire-in-conduit superconductor, comprising:
a. providing a wire matrix carrier having a long axis and a cylindrical external perimeter;
b. creating a plurality of holes through said wire matrix material, with said plurality of holes being parallel to said long axis;
c. providing a plurality of superconducting wires;
d. placing said plurality of superconducting wires in said plurality of holes in said wire matrix material to create a first assembly;
e. drawing said first assembly to reduce the diameter of said cylindrical external perimeter;
f. providing a hollow conduit having a square cross section and an internal wall boundary;
g. placing said first assembly within said internal wall boundary of said hollow conduit to form a second assembly; and
h. reducing the size of said conduit so that said internal wall boundary lies close to said cylindrical external perimeter of said first assembly, thereby forming four coolant channels between said conduit and said cylindrical external perimeter.

2. A method as recited in claim 1, further comprising after said step of drawing said first assembly to reduce the diameter of said cylindrical external perimeter, heat treating said first assembly.

3. A method as recited in claim 1, further comprising after said step of reducing the size of said conduit so that said internal wall boundary lies close to said cylindrical external perimeter of said first assembly, heat treating said first and second assemblies.

4. A method as recited in claim 1, further comprising adding an insulating layer over said hollow conduit.

5. A method as recited in claim 2, further comprising adding an insulating layer over said hollow conduit.

6. A method as recited in claim 3, further comprising adding an insulating layer over said hollow conduit.

7. A method as recited in claim 4, further comprising adding an insulating layer over said hollow conduit.

8. A method as recited in claim 4, further comprising winding said second assembly into a spool.

9. A method as recited in claim 5, further comprising winding said second assembly into a spool.

10. A method as recited in claim 6, further comprising winding said second assembly into a spool.

11. A method of making a wire-in-conduit superconductor, comprising:
a. providing a first conductor wherein at least a portion of said first conductor comprises a superconducting material, and wherein said first conductor has a long axis and a cylindrical external perimeter;
b. providing a hollow conduit having a square cross section and an internal wall boundary;
c. placing said first conductor within said internal wall boundary of said hollow conduit to form a first assembly; and
d. reducing the size of said conduit so that said internal wall boundary lies close to said cylindrical external perimeter of said first conductor, thereby forming four coolant channels between said conduit and said cylindrical external perimeter.

12. A method as recited in claim 11, further comprising after said step of reducing the size of said conduit so that said internal wall boundary lies close to said cylindrical external perimeter of said first conductor, heat treating said first assembly.

13. A method as recited in claim 11, further comprising adding an insulating layer over said hollow conduit to form a second assembly

14. A method as recited in claim 12, further comprising adding an insulating layer over said hollow conduit to form a second assembly.

15. A method as recited in claim 13, further comprising winding said second assembly into a spool.

16. A method as recited in claim 14, further comprising winding said second assembly into a spool.

17. A method of making a wire-in-conduit superconductor, comprising:
a. providing a first conductor wherein at least a portion of said first conductor comprises a superconducting material, and wherein said first conductor has a long axis and a cylindrical external perimeter;
b. providing a hollow conduit having a square cross section and an internal wall boundary;
c. placing said first conductor within said internal wall boundary of said hollow conduit to form a first assembly;
d. reducing the size of said conduit so that said internal wall boundary lies close to said cylindrical external perimeter of said first conductor, thereby forming four coolant channels between said conduit and said cylindrical external perimeter;
e. heat treating said first assembly; and
f. covering said first assembly in insulating material to form a second assembly.

18. A method as recited in claim 17, further comprising winding said second assembly into a spool.

19. A method as recited in claim 18, wherein said superconducting material comprises Bi-2212.

20. A method as recited in claim 1, wherein said superconducting wire comprises Bi-2212.
